(19) United States
(12) Patent Application Publication
(10) Pub. No.: US 2025/0309216 A1
(43) Pub. Date: Oct. 2, 2025

(54) RECONSTRUCTED SEMICONDUCTOR DIE EVALUATION IN STACKED MEMORY ARCHITECTURES

(71) Applicant: Micron Technology, Inc., Boise, ID (US)

(72) Inventors: Bharat Bhushan, Boise, ID (US); Sujeet V. Ayyapureddi, Boise, ID (US); Kunal R. Parekh, Boise, ID (US); Akshay N. Singh, Boise, ID (US)

(21) Appl. No.: 19/091,253

(22) Filed: Mar. 26, 2025

Related U.S. Application Data
(60) Provisional application No. 63/572,767, filed on Apr. 1, 2024.

(51) Int. Cl. H01L 25/18; H01L 23/00; H01L 23/48; H01L 23/522; H01L 23/528; H01L 25/00; H10B 12/00; H10B 80/00

(52) U.S. Cl. CPC H01L 25/18; H01L 23/481; H01L 23/5226; H01L 23/5283; H01L 25/50; H10B 12/01; H10B 80/00; H01L 24/13; H01L 24/32; H01L 2224/13023; H01L 2224/32227; H01L 2924/1436

(57) ABSTRACT

Methods, systems, and devices for reconstructed semiconductor die evaluation in stacked memory architectures are described. A semiconductor device may be formed based on reconstructed wafers of operable dies. In some examples, a first side of an interface block may be bonded with one or more volatile memory stacks. The interface block may also be formed with one or more conductive pads in a second side of the interface block which may provide an evaluation interface for the interface block and the one or more volatile memory stacks. The second side of the interface block may then be bonded to a host chip, and the host chip may be operable to couple with the interface block and control one or more functions of the interface block and the one or more volatile memory stacks.

### CROSS REFERENCE

The present Application for Patent claims priority to U.S. Patent Application No. 63/572,767 by Bhushan et al., entitled “RECONSTRUCTED SEMICONDUCTOR DIE EVALUATION IN STACKED MEMORY ARCHITECTURES,” filed Apr. 1, 2024, which is assigned to the assignee hereof, and which is expressly incorporated by reference in its entirety herein.

### TECHNICAL FIELD

The following relates to one or more semiconductor systems, including reconstructed semiconductor die evaluation in stacked memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

In some cases, techniques for manufacturing memory devices (e.g., or other semiconductor devices) may include wafer-to-wafer bonding. In wafer-to-wafer bonding, respective dies of each wafer may be bonded together without prior evaluation of each of the respective dies.

### BRIEF DESCRIPTION OF THE DRAWINGS

FIG. 1 shows an example of a system that supports reconstructed semiconductor die evaluation in stacked memory architectures in accordance with examples as disclosed herein.

FIG. 2 shows an example of a system that supports reconstructed semiconductor die evaluation in stacked memory architectures in accordance with examples as disclosed herein.

FIG. 3 shows an example of an architecture that supports reconstructed semiconductor die evaluation in stacked memory architectures in accordance with examples as disclosed herein.

FIGS. 4 through 10 show example operations for forming a semiconductor device a that supports reconstructed semiconductor die evaluation in stacked memory architectures in accordance with examples as disclosed herein.

FIG. 11 shows an example of a system that supports reconstructed semiconductor die evaluation in stacked memory architectures in accordance with examples as disclosed herein.

FIGS. 12 and 13 show flowcharts illustrating a method or methods that support reconstructed semiconductor die evaluation in stacked memory architectures in accordance with examples as disclosed herein.

### DETAILED DESCRIPTION

Some semiconductor systems (e.g., memory systems, processor systems, semiconductor devices) may include a stack of semiconductor components (e.g., semiconductor dies), which may include one or more memory dies (e.g., array dies, volatile memory dies) or one or more stacks of memory dies (e.g., volatile memory stacks) that are stacked with a logic die (e.g., an interface block) that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with one or more processors (e.g., one or more host chips), such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some semiconductor systems, such as a semiconductor device including one or more memory stacks (e.g., dynamic random access memory (DRAM) stacks, memory dies), one or more interface blocks (e.g., logic blocks, logic dies), and one or more host chips (e.g., GPUs), may be manufactured via one or more wafer-to-wafer bonding steps. In wafer-to-wafer bonding, a first wafer of multiple first dies, may be bonded to (e.g., via fusion bonding or hybrid bonding) a second wafer of multiple second dies. Accordingly, each first die of the first wafer may be bonded with a respective second die of a second wafer based on the wafer-to-wafer bonding. However, such bonding techniques may be associated with a relatively low device yield (e.g., a relatively high yield loss). For instance, each wafer may include both operable dies (e.g., good dies, dies the operate in accordance with a performance expectation) and defective dies (e.g., bad dies, dies that fail to operate in accordance with a performance expectation). As part of wafer-to-wafer bonding, an operable die of the first wafer may be bonded to a defective die of the second wafer, which may cause both dies to be rejected (e.g., discarded). Thus, some good dies may be discarded as part of a manufacturing process based on the wafer-to-wafer bonding, which may reduce a manufacturing yield of semiconductor devices and increase waste. Moreover, some manufacturing procedures may not support intermediate evaluation procedures (e.g., test procedures) to evaluate whether a die, or a combination of bonded dies, are operable prior to completion of the manufacturing process.

In accordance with one or more examples described herein, a semiconductor device (e.g., an HBM system, a heterogeneous semiconductor device) may be formed (e.g., manufactured) based on wafers that are reconstructed from dies that satisfy an evaluation procedure (e.g., dies that are known good dies (KGDs)). That is, some dies may be separated (e.g., diced) from one or more first wafers, tested to determine whether the dies are KGDs, and the KGDs are assembled together to form a second wafer. Additionally, manufacturing methods of semiconductor devices may be improved to support one or more evaluation procedures (e.g., intermediate evaluation procedures) as part of a formation process. In some examples, a first side (e.g., a backside, a side that includes a die substrate) of an interface block (e.g., a logic die, a known good logic die) may be bonded with one or more memory stacks (e.g., known good memory dies, DRAM stacks, 3D stacked memory, volatile memory stacks). The interface block may also be formed with one or more conductive pads (e.g., probe pads) in a second side (e.g., a frontside, a side that is opposite a die substrate) of the interface block, which may provide an evaluation interface (e.g., an interface operable to couple with evaluation circuitry) for the interface block and the one or more memory stacks. Based on performing one or more evaluation procedures, the second side of the interface block may then be bonded to a host chip (e.g., a known good host die, a GPU, one or more host devices), and the host chip may be operable to couple with the interface block and control one or more functions of the interface block and the one or more memory stacks. By forming semiconductor devices in accordance with one or more examples described herein, relatively fewer dies may be rejected, which may improve manufacturing yield. Additionally, performing intermediate evaluation procedures as part of the formation process may further reduce a likelihood of bonding good dies to defective dies, which may increase a yield of semiconductor devices and improve device reliability and performance.

In addition to applicability in memory systems as described herein, techniques for reconstructed semiconductor die evaluation in stacked memory architectures may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and reducing a quantity of rejected die components, which may improve efficiency of semiconductor device production and result in reduced electronic waste, among other benefits.

Features of the disclosure are illustrated and described in the context of systems and architectures. Features of the disclosure are further illustrated and described in the context of an architecture, illustrative operations for semiconductor device formation, and flowcharts.

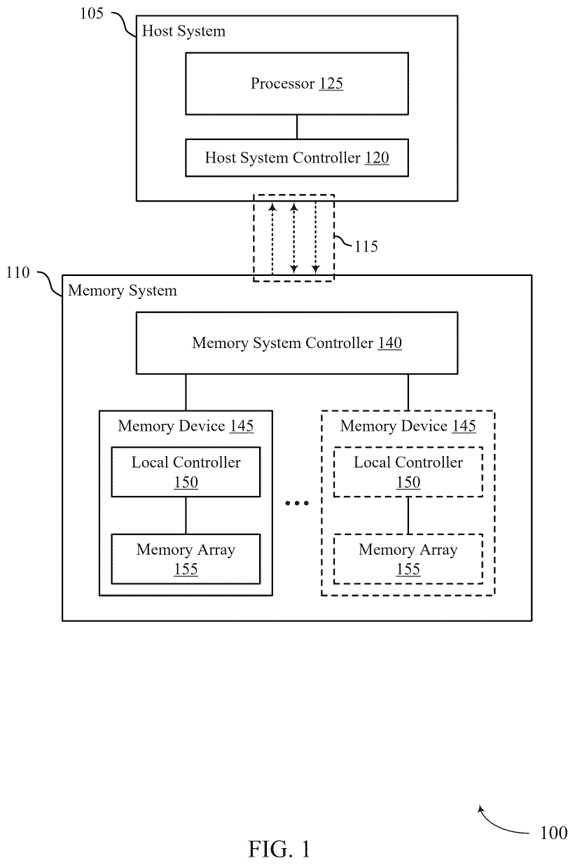

FIG. 1 shows an example of a system 100 that supports reconstructed semiconductor die evaluation in stacked memory architectures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, DRAM cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked die architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some systems 100 may be manufactured via one or more wafer-to-wafer bonding steps (e.g., blind wafer-to-wafer bonding steps, in which unevaluated dies of two or more wafers are bonded together). Some wafer-to-wafer bonding techniques may be associated with a relatively high yield loss. Moreover, some manufacturing procedures of a system 100 or portion thereof may not support evaluation procedures as part of manufacturing process. In accordance with one or more examples described herein, a system 100 or at least a portion thereof may be formed based on reconstructed wafers of KGDs. Additionally, manufacturing methods of systems 100 may be improved to support one or more evaluation procedures (e.g., intermediate evaluation procedures) as part of a formation process. For example, an interface block may be bonded with one or more memory stacks (e.g., stacks of memory devices 145). The interface block may also be formed with one or more conductive pads (e.g., probe pads) to provide an evaluation interface for the interface block and the one or more memory stacks. The interface block may then be bonded to a host chip (e.g., a host system 105), and the host chip may be operable to couple with the interface block and control one or more functions of the interface block and the one or more memory stacks. Such techniques may improve a manufacturing yield of semiconductor devices by reducing a quantity of rejected dies in a manufacturing process.

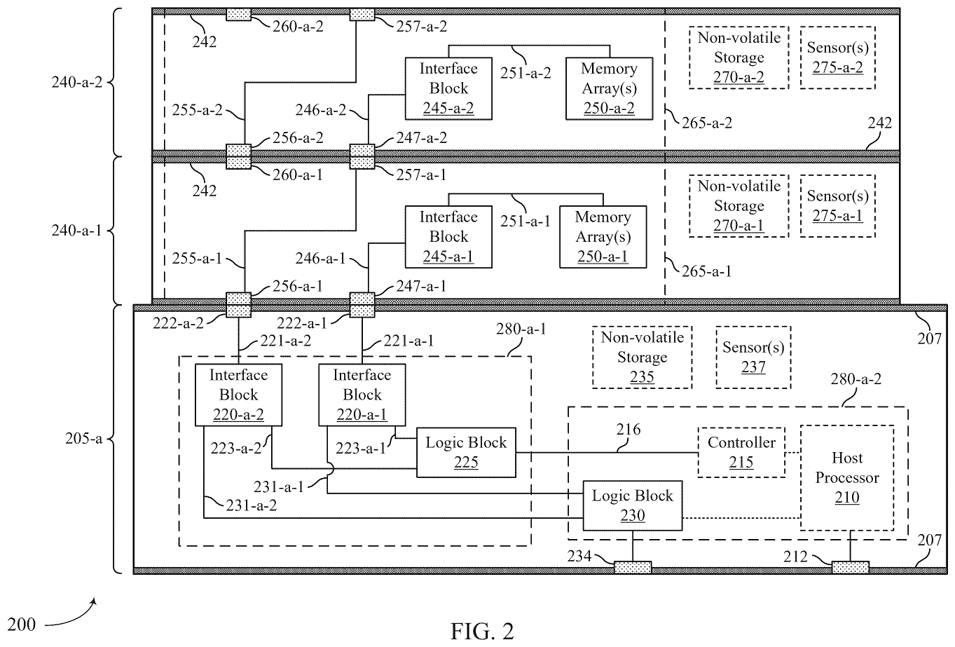

FIG. 2 shows an example of a system 200 (e.g., a semiconductor system, a system of coupled semiconductor dies, an HBM system, a 3D stacked memory system) that supports reconstructed semiconductor die evaluation in stacked memory architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). A hybrid bond may be an example of a permanent bond that combines a dielectric bond (SiOx) with embedded metal (Cu) to form interconnections. Hybrid bonding may enable smaller bonding pitches, higher memory cell density, improved signaling over conductive lines, improved power distribution, among other benefits. In an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some systems 200 may be manufactured via one or more wafer-to-wafer bonding steps (e.g., blind wafer-to-wafer bonding steps, in which unevaluated dies of two or more wafers are bonded together), which may be associated with a relatively high yield loss. Moreover, some manufacturing procedures of a system 200 or portion thereof may not support evaluation procedures as part of the manufacturing procedure. In accordance with one or more examples described herein, a system 200, or a portion thereof, may be formed based on reconstructed wafers of KGDs. Additionally, manufacturing methods of systems 200 may be improved to support one or more evaluation procedures (e.g., intermediate evaluation procedures) as part of a formation process. For example, a die 205 (e.g., including one or more interface blocks 220) may be bonded with one or more memory stacks (e.g., one or more sets of dies 240). The die 205 may also be formed with one or more conductive pads (e.g., probe pads) to provide an evaluation interface for the die 205 and the one or more dies 240. The die 240 may then be bonded to a host chip (e.g., a host system external to the die 205), and the host chip may be operable to couple with the die 205 and control one or more functions of the die 205 and the one or more dies 240. Such techniques may improve a manufacturing yield of systems 200 (or portions thereof) by reducing a quantity of rejected dies in a manufacturing process.

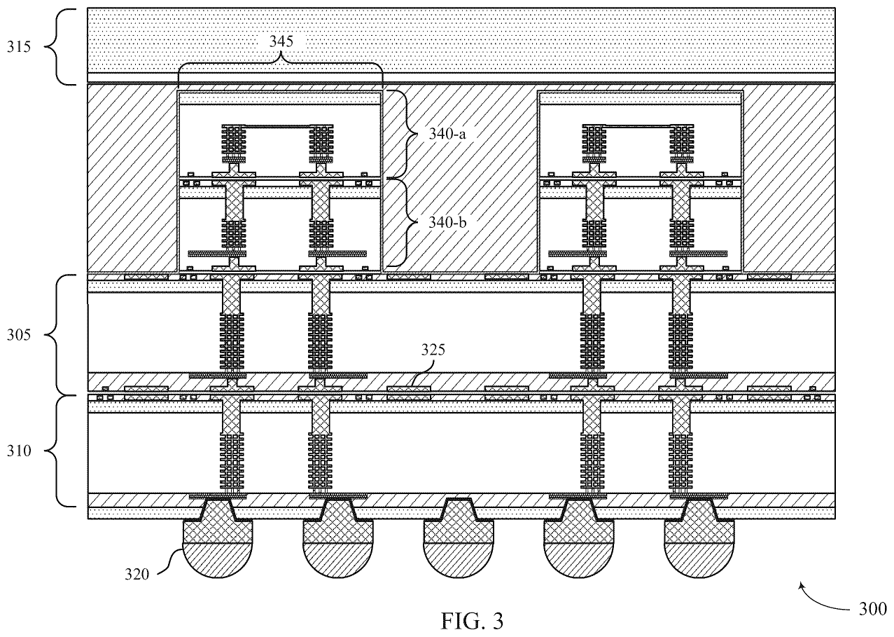

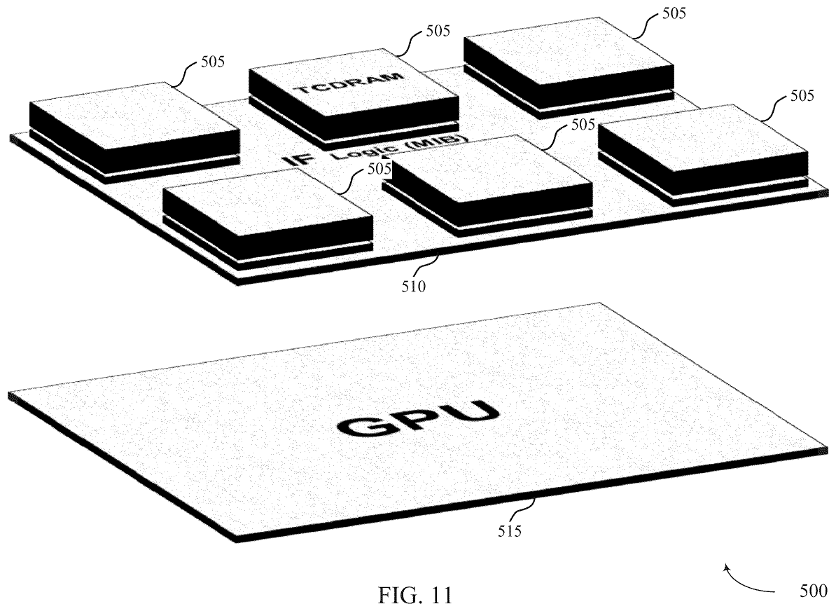

FIG. 3 shows an example of an architecture 300 that is a in stacked memory architectures in accordance with examples as disclosed herein. The architecture 300 may include an interface block 305 (e.g., interface logic, a logic chip, a die 205, an interface block 220, a logic layer), one or more memory stacks 345 (e.g., 3D stacked memory, memory devices 145), each memory stack 345 including one or more memory chips 340 (e.g., memory chips 340-a and 340-b, dies 240, DRAM dies, memory array dies, local controllers 150, memory arrays 155), a host chip 310 (e.g., a GPU, a host system 105, a host die, a host processor 210, a unit 280), a substrate 315 (e.g., a dummy layer, a silicon layer), and one or more solder pads 320 (e.g., solder contacts), which may represent examples of or include respective components as described herein, including with reference to FIGS. 1 and 2. Although a non-limiting example architecture 300 is illustrated in FIG. 3, the architecture 300 may include any quantity of memory stacks 345, interface blocks 305, host chips 310, and solder pads 320. In some examples, six memory stacks 345, one interface block 305, and one host chip 310 forming a 6-to-1-to-1 heterogeneous integration of 3D stacked memory, interface logic, and GPU, as shown with reference to FIG. 11. In another example, eight memory stacks 345, one interface block 305, and one host chip 310 forms an 8-to-1-to-1 heterogeneous integration of 3D stacked memory, interface logic, and GPU.

In some cases, the architecture 300 may be formed (e.g., manufactured) via one or more wafer-to-wafer bonding steps. As an example, a first wafer may include multiple interface blocks 305 and may be bonded to a second wafer that may include multiple host chips 310. Based on the bonding, each of the multiple interface blocks 305 of the first wafer may be coupled with (e.g., via one or more bond pads 325) a respective host chip 310 of the second wafer. In some other examples, a single interface block 305 obtainable after dicing of a first wafer may be bonded with host chip 310 of a second wafer. Such bonding is typically known as chip-to-wafer bonding. After the bonding, the respective sets of dies (e.g., a bonded pair of one interface block 305 and one host chip 310) may be diced for individual packaging. However, in some cases, a wafer may include both operable dies (e.g., good dies) and defective dies (e.g., bad dies, inoperable dies, faulty dies), and such wafer-to-wafer bonding may occur without a performance of an evaluation procedure on the respective wafers. Thus, in some cases, one or more good dies (e.g., an operable interface block 305) may be bonded with one or more bad dies (e.g., a bad host chip 310), which may cause some good dies to be rejected and discarded. Thus, such manufacturing techniques may result in a reduced manufacture yield and increased waste based on the rejection of good dies (e.g., that are bonded with bad dies).

In accordance with one or more examples described herein, an architecture 300 (e.g., a semiconductor device, an HBM system, a 3D stacked memory system, a heterogeneous semiconductor device) may be formed (e.g., manufactured) based on wafers that are reconstructed from dies that are verified to be operable (e.g., KGDs, dies that have satisfied an evaluation procedure). That is, KGDs (e.g., known good interface blocks 305, known good host chips 310, known good memory stacks 345) may be separated (e.g., diced) from one or more first wafers and assembled together to form a reconstructed wafer. In some examples, a “reconstructed wafer” may refer to a wafer that includes multiple dies (e.g., chips, die portions) that have been previously diced from other wafers and that are reformed together (e.g., aggregated, combined) based on a dielectric material (e.g., a dielectric silicon oxide gap fill material). Thus, a reconstructed die may include a relatively greater proportion of KGDs than one or more originally formed wafers from which the KGDs were diced. Accordingly, respective components of the architecture 300 may be verified as KGDs prior to bonding with other components. As such, the described examples provide for manufacturing procedures that are based on the bonding of multiple wafers/reconstructed wafers, which may increase a manufacturing yield (e.g., of the architecture 300).

Some examples and operations described herein may be described with reference to various sides of a respective component (e.g., an interface block 305, a host chip 310, a memory stacks 345, a memory chips 340, or some other component). For example, a side of a component may be referred to as a “backside” or a “frontside.” A “backside” of a component may refer to a side that is a same side as a substrate material (e.g., a silicon substrate) on which the component was formed (e.g., a substrate for mechanical support during formation). A “frontside” of a component may refer to a side that is opposite the substrate material on which the component was formed (e.g., opposite of the backside). For example, in some implementations, a backside of the interface block 305 may be bonded with a frontside of one or more memory stacks 345 and a frontside of the interface block 305 may be bonded with a backside of the host chip 310.

Moreover, one or more examples as described herein may support intermediate evaluation procedures (e.g., intermediate evaluation procedures) as part of a formation process, which may further improve manufacturing yield and improve a reliability of the architecture 300. In some examples, the interface block 305 may be formed with one or more conductive contacts (e.g., pads on the frontside of the interface block 305) to support probe contact during an evaluation procedure. Such conductive contacts may support intermediate evaluation procedures (e.g., of the interface block 305 and the one or more memory stacks 345) that may be performed during a formation process. By forming semiconductor devices in accordance with one or more examples described herein, systems such as the architecture 300 may be formed with a more testable design resulting in a relatively higher yield, reduced waste, and improved device reliability.

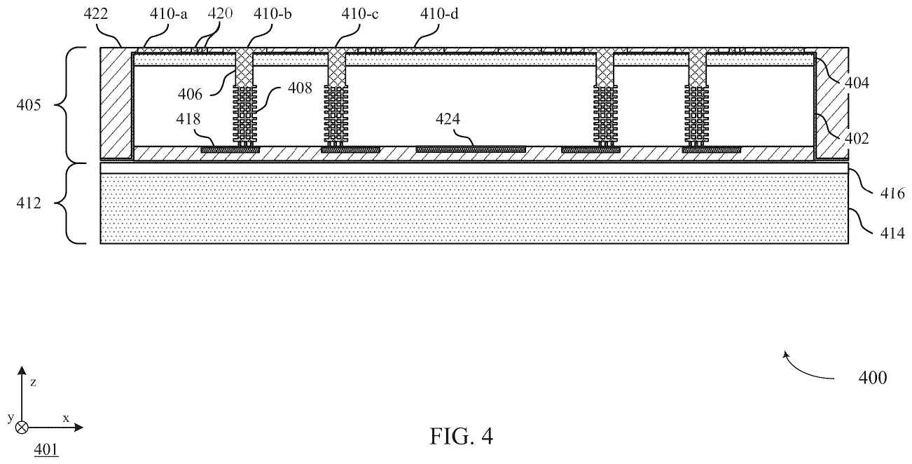

FIGS. 4 through 10 illustrate examples of operations for forming a semiconductor device 400 (e.g., a heterogeneous device, a semiconductor system of heterogeneous dies, a heterogeneous HBM system, a heterogeneous 3D stacked memory system) utilizing reconstructed semiconductor die evaluation in stacked memory architectures in accordance with examples as disclosed herein. For example, FIGS. 4 through 10 may illustrate aspects of a sequence of operations that may support manufacturing a system 100 or a portion thereof, a system 200 or a portion thereof, or some other device herein which may increase device yield during manufacturing and improve device reliability. Each of the figures may be described with reference to an x-direction, a y-direction, and a z-direction of the coordinate system 401. Operations illustrated in and described with reference to FIGS. 4 through 10 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques. In some examples, portions of the semiconductor device 400 that are illustrated with a same pattern may be formed of same or similar materials and portions that are illustrated with different patterns may be formed of different materials.

FIG. 4 illustrates a portion of the semiconductor device 400 after a first set of one or more manufacturing operations. For example, the first set of operations may include forming an interface block 405 (e.g., an interface logic die, a logic chip, a logic layer, a die 205, an interface block 220, an interface block 305). The interface block 405 may include logic circuitry that is configurable to operate one or more memory arrays of one or more memory stacks (e.g., 3D stacked memory). The interface block 405 may include one or more dielectric materials 402 and one or more substrate materials 404 (e.g., interface logic silicon). The one or more dielectric materials 402 may include, for example, one or more layers of silicon oxide materials, silicon carbon nitrate materials, or other dielectric materials. The one or more substrate materials 404 may include a silicon material or other substrate material. In some examples, one or more substrate materials 404, the one or more dielectric materials 402, or both may include (or be formed around) circuitry such as interconnection circuitry and transistor circuitry (e.g., complementary metal-oxide-semiconductor (CMOS) circuitry).

The interface block 405 may be formed with multiple vias 406 (e.g., TSVs, formed with a conductive material such as copper) through the first side (e.g., the backside) of the interface block 405 (e.g., based on a formation of multiple cavities and depositing a conductive material in the cavities). In some examples, the vias 406 may be formed using a via last process or via middle process. The vias 406 may be coupled with respective circuitry 408 of the interface block 405. The circuitry 408 may include back end of line (BEOL) circuitry (e.g., interconnection circuitry, one or more conductive paths formed above transistor circuitry, BEOL metals and vias) or other circuitry. In some examples, the interface block 405 may be formed with one or more conductive pads 410 (e.g., copper conductive pads, hybrid bond pads, conductive pads 410-a through 410-d) on a first side (e.g., a backside, a same side as the one or more substrate materials 404) of the interface block 405. At least some of the one or more conductive pads 410 may be coupled with respective vias 406 (e.g., conductive pads 410-b and 410-c). Accordingly, the one or more vias 406 may provide a communicative interface to the circuitry 408 via the one or more conductive pads 410. In some aspects, the vias 406 and conductive pads 410-a through 410-d are formed using process called dual damascene process. In some examples, bonding the first side of the interface block to other components (e.g., a memory stack) may be based on the one or more conductive pads 410. In some examples, one or more of the conductive pads 410 may be redundant pads (e.g., dummy pads, may not be used for bonding, conductive pad 410-a).

The interface block 405 may be positioned (e.g., formed) on a carrier material 412 (e.g., may be positioned above the carrier material 412 in a z direction). The carrier material 412 may include a sacrificial silicon material 414 and one or more dielectric materials 416. In some examples, at least a portion of the sacrificial silicon material 414 may be removed as part of a subsequent operation and the one or more dielectric materials 416 may be associated with bonding the interface block 405 to the carrier material 412. A second side of the interface block 405 (e.g., a frontside, a side opposite the one or more substrate materials 404) may be bonded (e.g., a chip-to-wafer front-to-front fusion bonding) to the carrier material 412 prior to bonding the first side to other components. The interface block 405 may also be formed with one or more contacts 418 (e.g., aluminum pads) to support a coupling of the interface block 405 with other components (e.g., with a host chip). In some examples, the interface block 405 may be formed with one or more alignment features 420 (e.g., formed of a conductive material) to support alignment with other dies or wafers during a bonding procedure. Additionally, the interface block 405 may be formed with one or more conductive pads 424 (e.g., probe pads formed of aluminum material) in the second side, which may provide an evaluation interface for the interface block 405. In some examples, the interface block 405 (e.g., the interface logic die) may be a full reticle size (e.g., a full mask size).

In some examples, the interface block 405 may be formed (e.g., diced) from a reconstructed wafer. That is, forming the interface block 405 may be based on forming a first wafer that includes a set of multiple interface blocks 405. Each interface block 405 of the set may be tested (e.g., evaluated) to determine whether an interface block 405 is defective (e.g., fails to satisfy a performance expectation) or operable (e.g., satisfies a performance expectation). The first wafer may then be diced to separate defective interface blocks 405 from operable interface blocks 405. Accordingly, an interface block 405 may be selected (e.g., for the semiconductor device 400) based on determining that the interface block 405 is operable (e.g., that the interface block 405 satisfies an evaluation operation). A second wafer (e.g., a reconstructed wafer) may be formed that includes the operable interface blocks 405 (e.g., KGDs, and excludes all defective interface blocks 405) based on the evaluation and selection process. The second wafer may be formed by forming (e.g., depositing, filling) one or more dielectric materials 422 (e.g., a silicon oxide gap fill) between each selected interface block 405 (e.g., between each KGDs of a set of KGDs). Thus, when diced, at least a portion of the one or more dielectric materials 422 may remain around the interface block 405. As such, bonding the interface block 405 to other components (e.g., one or more memory stacks) may be based on forming the second wafer, which may improve a yield of the semiconductor device 400 based on bonding one or more reconstructed wafers of KGDs.

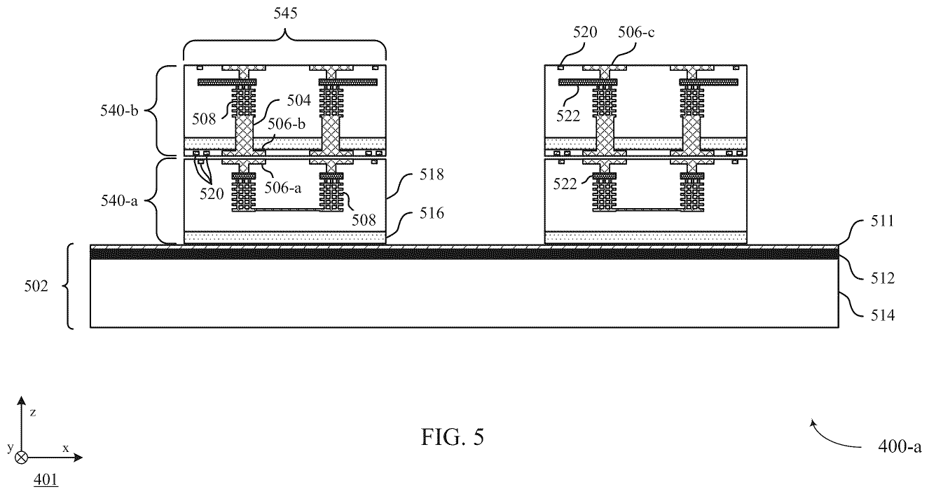

FIG. 5 illustrates a portion of a semiconductor device 400-a after a second set of one or more manufacturing operations. For example, the second set of operations may include post-dicing after forming one or more memory stacks 545 (e.g., 3D stacked memory, stacks of dies 240, memory devices 145) on a carrier material 502. In some examples, the memory stacks 545 may have been stacked using wafer-on-wafer bonding (e.g., post-dicing). Each memory stack 545 may include one or more memory chips 540 (e.g., dies 240, DRAM dies, memory arrays 155). Although FIG. 5 shows a non-limiting example in which each memory stack 545 includes a memory chip 540-a (e.g., a top DRAM) and a memory chip 540-b (e.g., a Corel DRAM), each respective memory stack 545 may include any quantity of memory chips 540, and any quantity of one or more memory stacks 545 may be formed on the carrier material 502. In one example, each memory stack 545 may include 8 memory chips 540. In another example, each memory stack 545 may include 12 memory chips 540. Finally, in another example, each memory may include 16 memory chips 540. In some examples, one or more vias 504 (e.g., TSVs, formed of a conductive copper material) may be formed in at least one memory chip 540 (e.g., memory chip 540-b) of each memory stack 545. The one or more vias 504 of each memory stack 545 may be formed using a via last or via middle process. In some examples, the memory chip 540-b may be coupled with the memory chip 540-a of a memory stack 545 based on the one or more vias 504. That is, each memory chip 540 may include circuitry 508 (e.g., interconnection circuitry, BEOL circuitry, BEOL metals and vias) which may be coupled with include one or more bond pads 506 (e.g., hybrid bond pads). The one or more bond pads 506 may support a bonding to another memory chip 540. For example, the memory chip 540-a may include one or more bond pads 506-a that are bonded via wafer-to-wafer front-to-back hybrid bond to one or more bond pads 506-b of the memory chip 540-b. In another example, the memory chip 540-a may include one or more bond pads 506-a that are bonded via chip-to-wafer front-to-back hybrid bond to one or more bond pads 506-b of the memory chip 540-b.

In some examples, a first side of the one or more memory stacks 545 (e.g., a backside of the top memory chip 540-a that is a same side as the substrate material 516) may be bonded to a release material 511 (e.g., a release layer, a silicon material) of the carrier material 502. The release material 511 may be bonded to a reusable carrier material 514 (e.g., a reusable glass material (de-opaqued)) via an adhesive material 512 (e.g., an adhesive layer). A second side of the one or more memory stacks 545 opposite the first side of the one or more memory stacks 545 (e.g., a frontside of the bottom memory chip 540-b that is opposite its respective substrate material 516) may support a bonding to other components (e.g., an interface block 405) based on one or more bond pads 506-c. In some examples, the one or more memory stacks 545 may be separated from the carrier material 502 (e.g., based on a stack plasma dicing and/or a partial laser release method for ultra-thin stacks) prior to bonding the one or more memory stacks 545 with other components. Each memory chip 540 may further include a substrate material 516 (e.g., silicon substrate), one or more dielectric materials 518 (e.g., including transistor (CMOS) cell circuitry, one or more layers of silicon oxide materials, silicon carbon nitrate materials, or other dielectric materials), one or more alignment features 520 (e.g., for bonding alignment), and one or more contacts 522 (e.g., aluminum contacts for coupling with a bond pad 506).

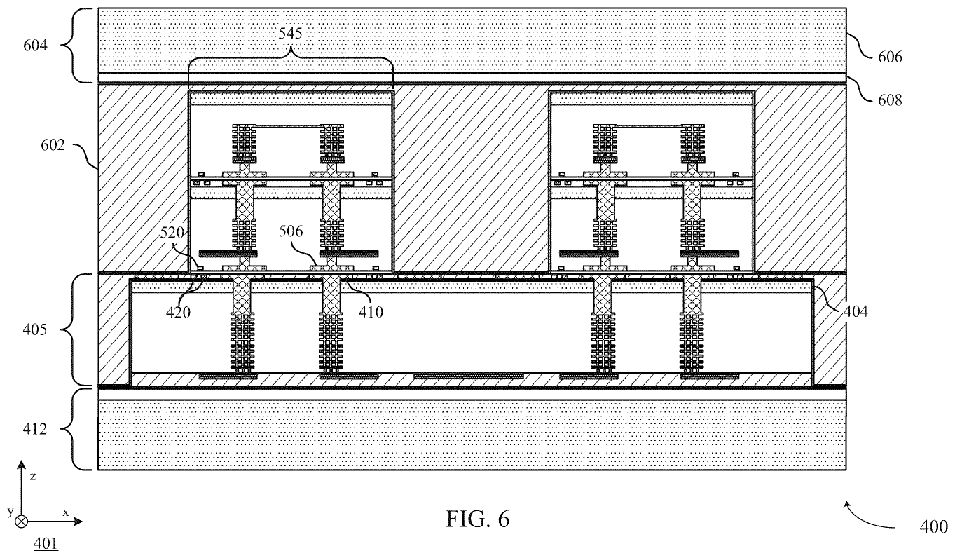

FIG. 6 illustrates a portion of the semiconductor device 400 after a third set of one or more manufacturing operations. For example, the third set of operations may include bonding (e.g., via a front-to-back stack-to-wafer hybrid bond) a first side of an interface block 405 (e.g., a backside of the interface block 405 that is a same side as the one or more substrate materials 404) to one or more memory stacks 545 (e.g., to a frontside of the one or more memory stacks 545). In some examples, one or more dielectric materials 602 (e.g., silicon oxide gap fill material) may be formed (e.g., deposited) between each memory stack 545 of the one or more memory stacks 545 (e.g., thus surrounding and separating respective substrates of each memory stack 545) after bonding the first side of the interface block 405 to the one or more memory stacks 545. Bonding the interface block 405 to the one or more memory stacks 545 may be based on the one or more conductive pads 410, the one or more bond pads 506, the one or more alignment features 420, the one or more alignment features 520, or any combination thereof. In some examples, the one or more memory stacks 545 (e.g., a backside of the one or more memory stacks 545) may be bonded (e.g., via a wafer-to-wafer front-to-back fusion bond, by a chip-to-wafer fusion bond) with a substrate 604 (e.g., including a silicon material 606 and a dielectric material 608). In some examples, the substrate 604 may be associated with thermal dissipation of the semiconductor device 400. Although the example of the semiconductor device 400 shows two memory stacks 545 bonded to the interface block 405, the semiconductor device 400 may include any quantity of memory stacks 545 bonded to any quantity of interface blocks 405 (e.g., at least one interface block 405 coupled with at least eight memory stacks 545).

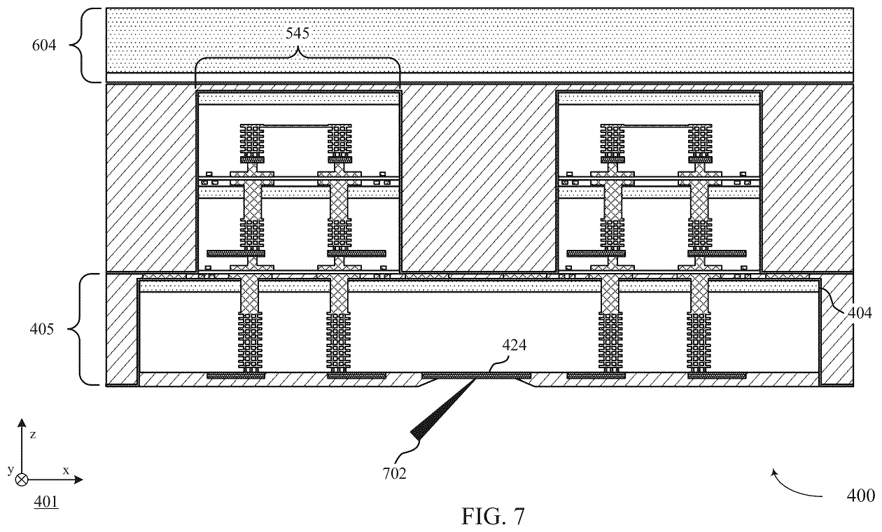

FIG. 7 illustrates a portion of the semiconductor device 400 after a fourth set of one or more manufacturing operations. For example, the fourth set of operations may include removing the carrier material 412 (e.g., the sacrificial carrier) and performing an evaluation procedure on the interface block 405 and the one or more memory stacks 545. The evaluation procedure may include probing (e.g., using a probe 702 or other evaluation circuitry) one or more conductive pads 424 (e.g., probe pads) of a side of the interface block 405 that is opposite the first side (e.g., a frontside of the interface block 405). The evaluation procedure may be based on (e.g., may occur after) bonding the first side of the interface block 405 (e.g., the backside of the interface block 405) to the one or more memory stacks 545. At this stage, the semiconductor device 400 may be supported (e.g., mechanically) by the substrate 604. In some examples, the evaluation procedure may include full functional testing of the one or more memory stacks 545 from the frontside of the interface block 405.

Accordingly, by forming the one or more conductive pads 424 and performing the evaluation procedure at this stage, the semiconductor device 400 may be evaluated prior to further formation or manufacturing operations. For example, a production yield of semiconductor devices 400 may increase by verifying operability of the interface block 405 and the one or more memory stacks 545 prior to bonding the semiconductor device 400 with other components (e.g., a host chip), thus mitigating a likelihood of bad-to-good die bond combinations.

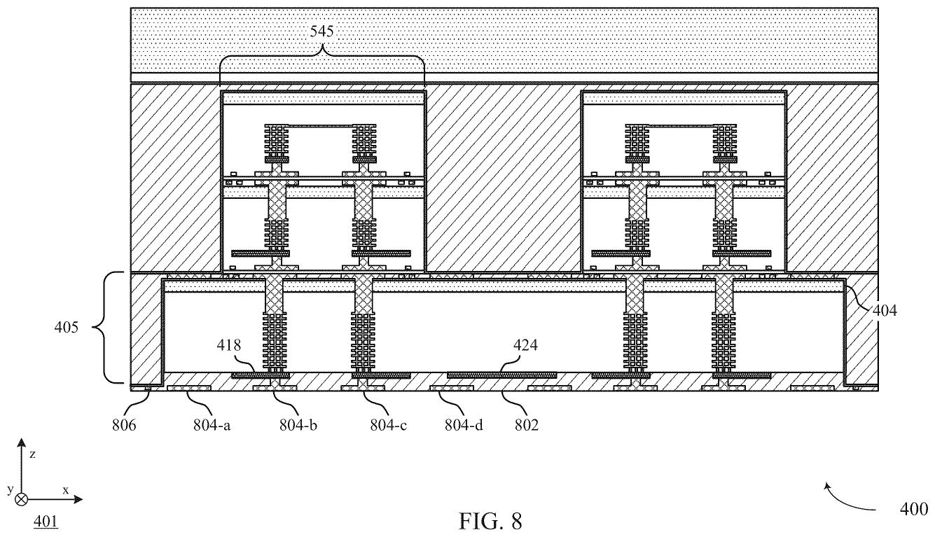

FIG. 8 illustrates a portion of the semiconductor device 400 after a fifth set of one or more manufacturing operations. For example, the fifth set of operations may include forming one or more dielectric materials 802 and forming one or more conductive pads 804 (e.g., bond pads, hybrid bond pads, conductive pad 804-a, conductive pad 804-b, conductive pad 804-c, conductive pad 804-d) in the one or more dielectric materials 802 and over the one or more contacts 418 and the one or more conductive pads 424. The one or more conductive pads 804 may be formed on a side of the interface block 405 that is opposite the one or more substrate materials 404 (e.g., the frontside of the interface block 405). At least some of the one or more conductive pads 804 may be coupled with respective contacts 418 of the interface block 405 (e.g., conductive pad 804-b and conductive pad 804-c). One or more alignment features 806 may also be formed in the one or more dielectric materials 802 to support alignment with other dies or wafers (e.g., a host chip 905) during a bonding procedure. In some examples, bonding the side of the interface block 405 to other components (e.g., a host chip) may be based on forming the one or more dielectric materials 802, the one or more conductive pads 804, the one or more alignment features 806, or any combination thereof.

In some examples, after the fifth set of manufacturing operations, the semiconductor device 400 may be ready for packaging, which may include separating (e.g., dicing) multiple semiconductor devices 400 (e.g., formed on a same carrier) from one another. That is, the semiconductor device 400 may be packaged for delivery without additional manufacturing operations (e.g., without bonding to a host chip, the semiconductor device 400 may not include a GPU). Such methods may enable a separate manufacture of the interface block 405 and one or more memory stacks 545 combination and other external components (e.g., such a host system).

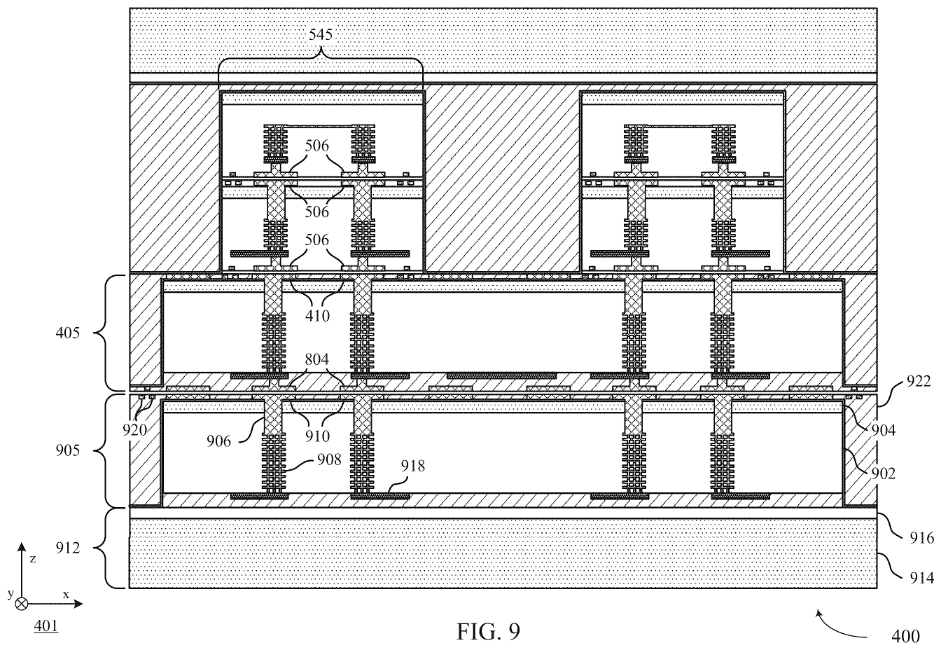

FIG. 9 illustrates a portion of the semiconductor device 400 after a sixth set of one or more manufacturing operations. For example, the sixth set of operations may include forming a host chip 905 (e.g., a GPU, a host system 105, a host die, a host processor 210, a unit 280). The host chip 905 may include GPU that is operable to control one or more functions of the interface block 405, the one or more memory stacks 545, or both. The host chip 905 may include one or more dielectric materials 902 and one or more substrate materials 904 (e.g., GPU silicon). The one or more dielectric materials 902 may include, for example, one or more layers of silicon oxide materials, silicon carbon nitrate materials, or other dielectric materials. The one or more substrate materials 904 may include a silicon material or other substrate material. In some examples, one or more substrate materials 904, the one or more dielectric materials 902, or both may include (or be formed around) circuitry such as interconnection circuitry and transistor circuitry (e.g., CMOS circuitry).

The host chip 905 may be formed with a set of multiple vias 906 (e.g., TSVs, formed with a conductive material such as copper) through a first side of the host chip 905 that is the same side as the one or more substrate materials 904 (e.g., a backside of the host chip 905). The vias 906 may be coupled with respective circuitry 908 of the host chip 905. The circuitry 908 may include interconnection circuitry (e.g., BEOL circuitry, BEOL metals and vias, one or more conductive paths formed above transistor circuitry) or other circuitry. In some examples, the host chip 905 may be formed with one or more conductive pads 910 (e.g., copper conductive pads, hybrid bond pads) on the first side (e.g., the backside) of the host chip 905. At least some of vias 906 may be coupled with respective conductive pads 910. Accordingly, the one or more vias 906 may provide an interface to the circuitry 908 via the one or more conductive pads 910.

The host chip 905 may be positioned (e.g., formed) on a carrier material 912 (e.g., above the carrier material 912 along a z direction), and a second side of the host chip 905 that is opposite the one or more substrate materials 904 (e.g., a frontside of the host chip 905) may be bonded (e.g., via chip-to-wafer front-to-front fusion bonding for a reconstructed wafer, via wafer-to-wafer front-to-front fusion bonding with the carrier substrate for a non-reconstructed wafer) to the carrier material 912. The carrier material 912 may include a sacrificial silicon substrate material 914 and one or more dielectric materials 916. In some examples, at least a portion of the sacrificial silicon substrate material 914 may be removed as part of a subsequent operation and the one or more dielectric materials 916 may be associated with bonding the host chip 905 to the carrier material 912. The second side of the host chip 905 may be bonded to the carrier material 912 prior to bonding the interface block 405 to the host chip 905. The host chip 905 may also be formed with one or more contacts 918 (e.g., aluminum pads) to support a coupling of the host chip 905 with other components (e.g., solder pads, probe testing). In some examples, the host chip 905 may be formed with one or more alignment features 920 (e.g., formed of a conductive material) to support alignment with other dies or wafers (e.g., an interface block 405 or a wafer of interface blocks 405) during a bonding procedure.

The interface block 405 (e.g., a frontside of the interface block 405) may be bonded (e.g., via a wafer-to-wafer front-to-back hybrid bond, via a chip-to-wafer front-to-back hybrid bond) to the host chip 905 (e.g., the backside of the host chip 905). Specifically, one or more conductive pads 804 in a frontside of the interface block 405 may be bonded to one or more conductive pads 910 in a backside of the host chip 905. That is, the bonding of the interface block 405 and the host chip 905 may be based on the one or more conductive pads 910, the one or more conductive pads 804, or both. In some examples, if a chip-to-wafer configuration is used, the one or more dielectric materials 802 may surround the interface block 405 and the one or more dielectric materials 922 may surround the host chip 905. Alternatively, if a wafer-to-wafer configuration is used, the one or more dielectric materials 802 and the one or more dielectric materials 922 may not be present. In some examples, the vias 906 may be aligned with the vias 406. Additionally, bonding the interface block 405 to the host chip 905 may be based on performing an evaluation procedure (e.g., as described herein, including with reference to FIG. 7). Based on the bonding, the host chip 905 may be operable to communicatively couple with the interface block 405 and control one or more functions of the one or more memory stacks 545 (e.g., including read operations, write operations, memory management operations, and maintenance operations, among other examples). Thus, based on the sixth set of operations, multiple memory stacks 545 may be stacked over both an interface block 405 and a host chip 905 (e.g., over a stack of a logic die and a GPU die).

In some examples, the interface block 405 and the host chip 905 (e.g., the stack of logic and GPU dies) may have identical lateral dimensions (e.g., a same length along a width direction of the semiconductor device 400). Such identical dimensions may facilitate wafer-on-wafer integration. In some alternative examples, the interface block 405 and the host chip 905 (e.g., the stack of logic and GPU dies) may have different lateral dimensions (e.g., different respective lengths along a width direction of the semiconductor device 400). In such examples, one or more dielectric materials (e.g., a silicon oxide material) may be on the sides of any die (e.g., the interface block 405, the host chip 905) with a relatively smaller lateral dimension than the other.

In some examples, the host chip 905 may be formed (e.g., diced) from a reconstructed wafer. That is, forming the host chip 905 may be based on forming a first wafer that includes a set of multiple host chips 905. Each host chip 905 of the set may be tested (e.g., evaluated) to determine whether a host chip 905 is defective (e.g., fails to satisfy a performance expectation) or operable (e.g., satisfies a performance expectation). The first wafer may then be diced to separate host chip 905 from operable host chip 905. Accordingly, a host chip 905 may be selected (e.g., for the semiconductor device 400) based on determining that the host chip 905 is operable. A second wafer (e.g., a reconstructed wafer) may be formed that includes the operable host chips 905 (e.g., KGDs, and excludes all defective host chip 905) based on the evaluation and selection process. The second wafer may be formed by forming (e.g., depositing, filling) one or more dielectric materials 922 (e.g., a silicon oxide gap fill) between each selected host chip 905. Thus, when diced, at least a portion of the one or more dielectric materials 922 may remain around each host chip 905. As such, bonding the host chip 905 to the interface block 405 may be based on forming the second wafer, which may improve a yield of the semiconductor device 400 based on bonding one or more reconstructed wafers of KGDs (e.g., a wafer-to-wafer front-to-back hybrid bond between a reconstructed wafer of interface blocks 405 and a reconstructed wafer of host chips 905).

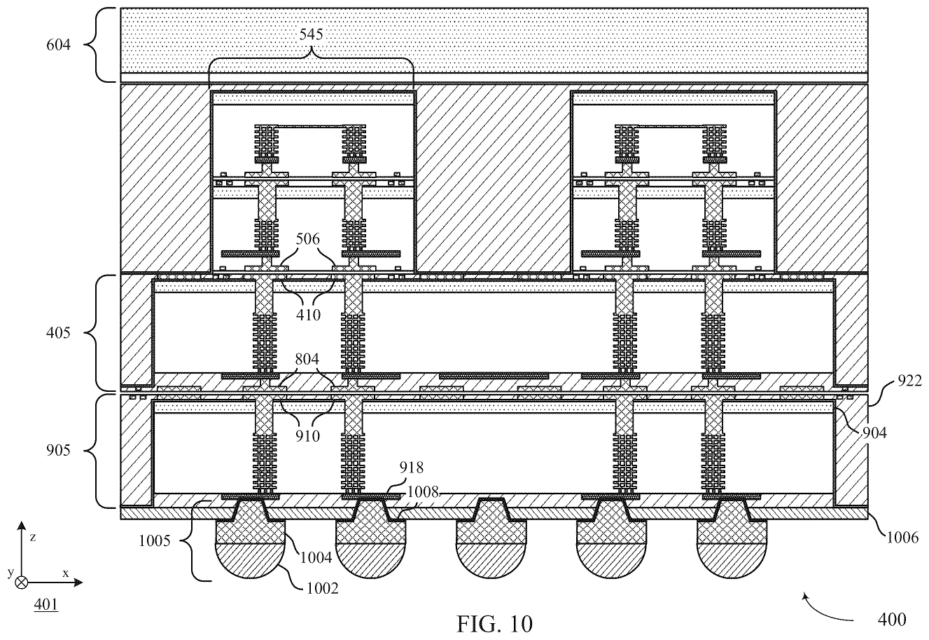

FIG. 10 illustrates a portion of the semiconductor device 400 after a seventh set of one or more manufacturing operations. For example, the seventh set of operations may include forming one or more solder pads 1005 (e.g., μ-bumps, electrical contacts). Each solder pad 1005 may include a solder material 1002 (e.g., solder balls) coupled with a conductive material 1004 (e.g., copper). The one or more solder pads 1005 may be formed below (e.g., along a z direction) a side of the host chip 905 that is opposite the one or more substrate materials 904 of the host chip 905 (e.g., below a frontside of the host chip 905). In some examples, forming the one or more solder pads 1005 may include removing the carrier material 912 and depositing one or more substrate materials 1006 (e.g., a polyimide material) over the frontside of the host chip 905. Then, one or more cavities may be formed through at least a portion of the one or more substrate materials 1006 and the one or more dielectric materials 922 to reach the one or more contacts 918. The conductive material 1004 may be deposited in the one or more cavities, and the solder material 1002 may be formed over the conductive material 1004. In some examples, a second conductive material 1008 (e.g., tungsten) may be formed between the conductive material 1004 and the one or more contacts 918. Thus, the one or more solder pads 1005 may provide an interface with the host chip 905 via the one or more contacts 918. In some examples, the frontside of the host chip 905 may be coupled with the one or more solder pads 1005, may include the one or more contacts 918 (e.g., aluminum pads for probe testing), and may have a polyimide layer (e.g., the one or more substrate materials 1006).

After the seventh set of manufacturing operations, the semiconductor device 400 may be ready for packaging, which may include separating (e.g., dicing) multiple semiconductor devices 400 (e.g., formed on a same carrier) from one another. In accordance with the techniques as described with reference to FIGS. 4 through 10, the semiconductor device 400 may include a heterogeneous integration of a host chip 905 (e.g., a GPU), an interface block 405 (e.g., interface logic), and one or more memory stacks 545 (e.g., 3D stacked memory). That is, the semiconductor device 400 may include a host chip 905 that is bonded to a frontside of an interface block 405 via the one or more conductive pads 910 and the one or more conductive pads 804. The semiconductor device 400 may further include one or more memory stacks 545 that are bonded to a backside of the interface block 405 via the one or more conductive pads 410 and the one or more bond pads 506. The substrate 604 may be formed above the one or more memory stacks 545 such that the semiconductor device 400 meets a height constraint (e.g., along the z direction). In some examples, the semiconductor device 400 may be a multi-bonding integration assembly, where the one or more memory stacks 545 (e.g., a first stack of DRAM dies) are stacked using wafer-on-wafer bonding, and the interface block 405 and the host chip 905 (e.g., a second stack of a logic die and a GPU die) may also be stacked using wafer-on-wafer bonding. Further, the one or more memory stacks 545 (e.g., the first stack) may be placed on the interface block 405 and the host chip 905 (e.g., the second stack) via a chip-on-wafer bonding or stack-on-wafer (SoW) bonding. In some examples, the one or more memory stacks 545 (e.g., each memory chip of the one or more memory stacks 545) may be stacked in a front-to-back configuration on a stack of the interface block 405 and a host chip 905 which may also be stacked in a front-to-back configuration.

Utilizing one or more techniques as described herein may support an increased manufacturing yield for wafers associated with components of semiconductor devices 400 (e.g., HBM devices, 3D stacked memory devices). For example, the techniques herein enable intermediate evaluation prior to a bonding procedure, which may reduce a likelihood of good die to bad die bonding. Additionally, the described techniques may support bonding of reconstructed wafers which may further increase a manufacturing yield and reduced waste based on an increased quantity of good die to good die combinations. Accordingly, manufacturing of semiconductor device 400 may be associated with an increased yield and a semiconductor device 400 may operate with increased reliability.

Although some of the described techniques are described in the context of memory systems, the techniques described herein may be implemented in other semiconductor systems that implement heterogeneous semiconductor components (e.g., dies associated with different functions, including different logic functions, different storage or processing functions, or any combination thereof), including heterogeneous semiconductor components that are interconnected within a layer, between layers, or any combination thereof. Moreover, although the non-limiting example of the semiconductor device 400 is illustrated as a heterogeneous integration between two memory stacks 545, one interface block 405, and one host chip 905, it is to be understood that the techniques described herein may apply to any configuration including one or more memory stacks 545, one or more interface blocks 405, one or more host chips 905, or any combination thereof (e.g., six memory stacks 545, one interface block 405, and one host chip 905).

FIG. 11 illustrates an example of a semiconductor device 500 formed using the techniques described herein. The semiconductor device 500 is an example 6-to-1-to-1 integration of memory stacks. For example, the semiconductor device 500 includes memory stacks 505 (e.g., labeled 3D stacked memory), one interface block 510 (e.g., labeled IF Logic (MIB)), and one host chip 515 (e.g., labeled GPU). The memory stacks 505 may be examples of memory stacks 345 and memory stacks 545 as described with references to FIGS. 3-10. The interface block 510 may be an example of an interface block 305 and an interface block 405 as described with references to FIGS. 3-10. The host chip 515 may be an example of a host chip 310 and a host chip 905 as described with references to FIGS. 3-10.

While the semiconductor device 500 shows a particular configuration of memory stacks 505, interface block 510, and host chip 515, various combinations components are within the scope of this disclosure. For example, the techniques described herein may be used to from semiconductor device of X-to-1-to-1 integration of memory stacks, where X represents the quantity of memory stacks 505 in the semiconductor device and X may be 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, etc. quantity of memory stacks. In some examples, the techniques described herein may be used to from semiconductor device of 6-to-Y-to-1 integration of memory stacks, where Y represents the quantity of interface blocks 510 in the semiconductor device and Y may be 1, 2, 3, 4, 5, 6, etc. In some examples, the techniques described herein may be used to from semiconductor device of 6-to-1-to-Z integration of memory stacks, where Z represents the quantity of host chips 515 in the semiconductor device and Z may be 1, 2, 3, 4, 5, 6, etc.

Other configurations of semiconductor devices may be formed using the techniques described here. In some examples, the techniques described herein may be used to from semiconductor device of X-to-Y-to-Z integration of memory stacks, where X represents the quantity of memory stacks 505 in the semiconductor device, Y represents the quantity of interface blocks 510 in the semiconductor device and Z represents the quantity of host chips 515 in the semiconductor device. Different configurations of the semiconductor device may include (but are not limited to): 2-to-2-to-1, 4-to-2-to-1, 8-to-2-to-1, 10-to-2-to-1, 12-to-2-to-1, 14-to-2-to-1, 16-to-2-to-1, etc.; or 3-to-3-to-1, 9-to-3-to-1, 12-to-3-to-1, 15-to-3-to-1, etc.; or 4-to-4-to-1, 8-to-4-to-1, 12-to-4-to-1, 16-to-4-to-1, etc.; or 12-to-6-to-1, 18-to-6-to-1, 24-to-6-to-1, etc.; or 8-to-8-to-1, 16-to-8-to-1, 24-to-8-to-1, 32-to-8-to-1, etc.; or 4-to-2-to-2, 8-to-2-to-2, 10-to-2-to-2, 12-to-2-to-2, 14-to-2-to-2, 16-to-2-to-2, etc.; or 9-to-3-to-3, 12-to-3-to-3, 12-to-6-to-3, 15-to-3-to-3, etc.; or 4-to-4-to-2, 8-to-4-to-2, 12-to-4-to-2, 16-to-4-to-2, etc.; or 12-to-6-to-2, 18-to-6-to-2, 24-to-6-to-2, etc.; or 12-to-6-to-3, 18-to-6-to-3, 24-to-6-to-3, etc.; or 8-to-8-to-2, 16-to-8-to-2, 24-to-8-to-2, 32-to-8-to-2, etc.; or 8-to-8-to-4, 16-to-8-to-4, 24-to-8-to-4, 32-to-8-to-4, etc. Other numeric combinations of components may also be formed using the techniques described herein.

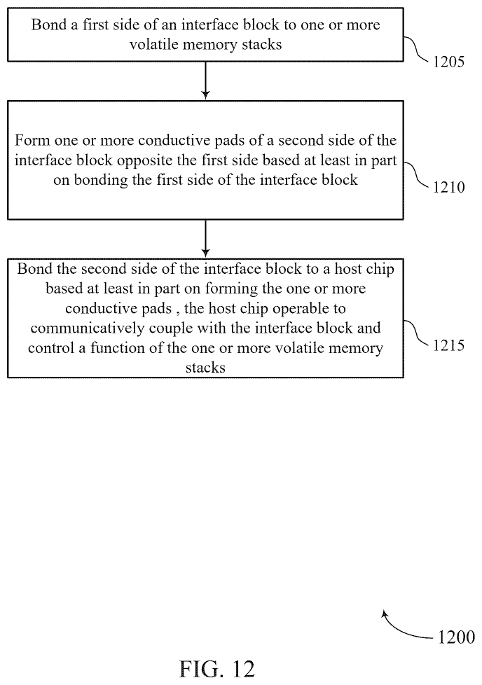

FIG. 12 shows a flowchart illustrating a method 1200 that supports reconstructed semiconductor die evaluation in stacked memory architectures in accordance with examples as disclosed herein. The operations of method 1200 may be implemented by a manufacturing system or its components as described herein. For example, the operations of method 1200 may be performed by a manufacturing system as described with reference to FIGS. 1 through 11. In some examples, a manufacturing system may execute a set of instructions to control the functional elements of the device to perform the described functions. Additionally, or alternatively, the manufacturing system may perform aspects of the described functions using special-purpose hardware.

At 1205, the method may include bonding a first side of an interface block to one or more volatile memory stacks.

At 1210, the method may include forming one or more conductive pads of a second side of the interface block opposite the first side based at least in part on bonding the first side of the interface block.

At 1215, the method may include bonding the second side of the interface block to a host chip based at least in part on forming the one or more conductive pads, the host chip operable to communicatively couple with the interface block and control a function of the one or more volatile memory stacks.

In some examples, an apparatus as described herein may perform a method or methods, such as the method 1200. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for bonding a first side of an interface block to one or more volatile memory stacks; forming one or more conductive pads of a second side of the interface block opposite the first side based at least in part on bonding the first side of the interface block; and bonding the second side of the interface block to a host chip based at least in part on forming the one or more conductive pads, the host chip operable to communicatively couple with the interface block and control a function of the one or more volatile memory stacks.

Aspect 2: The method, apparatus, or non-transitory computer-readable medium of aspect 1, further including operations, features, circuitry, logic, means, or instructions, or any combination thereof for forming the interface block positioned on a carrier material, the interface block including one or more second conductive pads on the first side of the interface block, where; bonding the first side of the interface block to the one or more volatile memory stacks is based at least in part on the one or more second conductive pads; and the second side of the interface block is bonded to the carrier material prior to bonding the first side of the interface block.

Aspect 3: The method, apparatus, or non-transitory computer-readable medium of aspect 2, further including operations, features, circuitry, logic, means, or instructions, or any combination thereof for forming a plurality of vias through the first side of the interface block, the plurality of vias coupled with the one or more second conductive pads.

Aspect 4: The method, apparatus, or non-transitory computer-readable medium of any of aspects 2 through 3, further including operations, features, circuitry, logic, means, or instructions, or any combination thereof for forming a first wafer including a plurality of interface blocks including the interface block; testing the plurality of interface blocks to determine whether each interface block is defective; and dicing the first wafer to separate defective interface blocks from operable interface blocks.

Aspect 5: The method, apparatus, or non-transitory computer-readable medium of aspect 4, further including operations, features, circuitry, logic, means, or instructions, or any combination thereof for selecting the interface block based at least in part on determining that the interface block is operable and forming a second wafer including the operable interface blocks including the interface block based at least in part on selecting the interface block, where bonding the interface block to the one or more volatile memory stacks is based at least in part on forming the second wafer.

Aspect 6: The method, apparatus, or non-transitory computer-readable medium of any of aspects 1 through 5, further including operations, features, circuitry, logic, means, or instructions, or any combination thereof for forming the one or more volatile memory stacks on a carrier material and separating the one or more volatile memory stacks from the carrier material prior to bonding the first side of the interface block to the one or more volatile memory stacks.

Aspect 7: The method, apparatus, or non-transitory computer-readable medium of aspect 6, further including operations, features, circuitry, logic, means, or instructions, or any combination thereof for forming a plurality of vias in at least a first volatile memory of each volatile memory stack, where the first volatile memory is coupled with a second volatile memory of a volatile memory stack based at least in part on the plurality of vias.

Aspect 8: The method, apparatus, or non-transitory computer-readable medium of any of aspects 6 through 7, further including operations, features, circuitry, logic, means, or instructions, or any combination thereof for forming a dielectric material between each volatile memory stack of the one or more volatile memory stacks after bonding the first side of the interface block to the one or more volatile memory stacks and bonding a first side of the one or more volatile memory stacks to a silicon material, where a second side of the one or more volatile memory stacks opposite the first side of the one or more volatile memory stacks is bonded to the first side of the interface block.

Aspect 9: The method, apparatus, or non-transitory computer-readable medium of any of aspects 1 through 8, further including operations, features, circuitry, logic, means, or instructions, or any combination thereof for performing an evaluation procedure on the interface block and the one or more volatile memory stacks by probing the one or more conductive pads in the second side of the interface block, where performing the evaluation procedure is based at least in part on forming the one or more conductive pads.

Aspect 10: The method, apparatus, or non-transitory computer-readable medium of aspect 9, further including operations, features, circuitry, logic, means, or instructions, or any combination thereof for forming one or more second conductive pads over the one or more conductive pads on the second side of the interface block, where bonding the second side of the interface block to the host chip is based at least in part on forming the one or more second conductive pads.

Aspect 11: The method, apparatus, or non-transitory computer-readable medium of any of aspects 1 through 10, further including operations, features, circuitry, logic, means, or instructions, or any combination thereof for forming the host chip positioned on a carrier material, the host chip including one or more second conductive pads in a first side of the host chip, where; bonding the second side of the interface block to the host chip includes bonding the second side of the interface block to the first side of the host chip based at least in part on the one or more second conductive pads; and a second side of the host chip opposite the first side of the host chip is bonded to the carrier material prior to bonding the second side of the interface block to the host chip.

Aspect 12: The method, apparatus, or non-transitory computer-readable medium of aspect 11, further including operations, features, circuitry, logic, means, or instructions, or any combination thereof for forming a plurality of vias through the first side of the host chip, the plurality of vias coupled with the one or more second conductive pads.

Aspect 13: The method, apparatus, or non-transitory computer-readable medium of any of aspects 11 through 12, further including operations, features, circuitry, logic, means, or instructions, or any combination thereof for forming a first wafer including a plurality of host chips including the host chip; testing the plurality of host chips to determine whether each host chip is defective; and dicing the first wafer to separate defective host chips from operable host chips.

Aspect 14: The method, apparatus, or non-transitory computer-readable medium of aspect 13, further including operations, features, circuitry, logic, means, or instructions, or any combination thereof for selecting the host chip based at least in part on determining that the host chip is operable and forming a second wafer including the operable host chips including the host chip based at least in part on selecting the host chip, where bonding the interface block to the host chip is based at least in part on forming the second wafer.

Aspect 15: The method, apparatus, or non-transitory computer-readable medium of any of aspects 1 through 14, further including operations, features, circuitry, logic, means, or instructions, or any combination thereof for forming one or more solder pads coupled with the host chip, where a first side of the host chip is bonded with the second side of the interface block, and where the one or more solder pads are formed below a second side of the host chip opposite the first side of the host chip.

Aspect 16: The method, apparatus, or non-transitory computer-readable medium of any of aspects 1 through 15, where the interface block includes logic circuitry that is configurable to operate one or more memory arrays of the one or more volatile memory stacks; the one or more volatile memory stacks include one or more DRAM chips including the one or more memory arrays; and the host chip includes a graphics processing unit that is operable to control a function of the interface block, the one or more volatile memory stacks, or both.

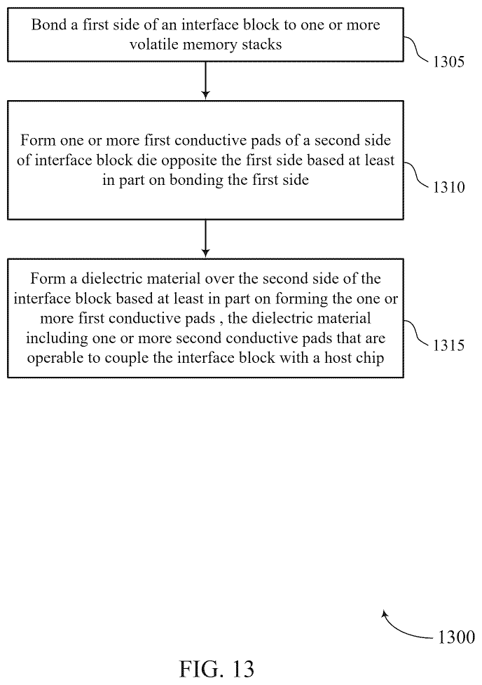

FIG. 13 shows a flowchart illustrating a method 1300 that supports reconstructed semiconductor die evaluation in stacked memory architectures in accordance with examples as disclosed herein. The operations of method 1300 may be implemented by a manufacturing system or its components as described herein. For example, the operations of method 1300 may be performed by a manufacturing system as described with reference to FIGS. 1 through 11. In some examples, a manufacturing system may execute a set of instructions to control the functional elements of the device to perform the described functions. Additionally, or alternatively, the manufacturing system may perform aspects of the described functions using special-purpose hardware.

At 1305, the method may include bonding a first side of an interface block to one or more volatile memory stacks.

At 1310, the method may include forming one or more first conductive pads of a second side of interface block die opposite the first side based at least in part on bonding the first side.

At 1315, the method may include forming a dielectric material over the second side of the interface block based at least in part on forming the one or more first conductive pads, the dielectric material including one or more second conductive pads that are operable to couple the interface block with a host chip.

In some examples, an apparatus as described herein may perform a method or methods, such as the method 1300. The apparatus may include features, circuitry, logic, means, or instructions (e.g., a non-transitory computer-readable medium storing instructions executable by a processor), or any combination thereof for performing the following aspects of the present disclosure:

Aspect 17: A method, apparatus, or non-transitory computer-readable medium including operations, features, circuitry, logic, means, or instructions, or any combination thereof for bonding a first side of an interface block to one or more volatile memory stacks; forming one or more first conductive pads of a second side of interface block die opposite the first side based at least in part on bonding the first side; and forming a dielectric material over the second side of the interface block based at least in part on forming the one or more first conductive pads, the dielectric material including one or more second conductive pads that are operable to couple the interface block with a host chip.

Aspect 18: The method, apparatus, or non-transitory computer-readable medium of aspect 17, further including operations, features, circuitry, logic, means, or instructions, or any combination thereof for forming the interface block positioned on a carrier material, the interface block including one or more third conductive pads on the first side of the interface block, where; bonding the first side of the interface block to the one or more volatile memory stacks is based at least in part on the one or more third conductive pads; and the second side of the interface block is bonded to the carrier material prior to bonding the first side of the interface block.

Aspect 19: The method, apparatus, or non-transitory computer-readable medium of any of aspects 17 through 18, further including operations, features, circuitry, logic, means, or instructions, or any combination thereof for forming the one or more volatile memory stacks on a carrier material and separating the one or more volatile memory stacks from the carrier material prior to bonding the first side of the interface block to the one or more volatile memory stacks.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 20: A semiconductor device, including: an interface block including logic circuitry configured to operate one or more memory arrays; one or more volatile memory stacks bonded to a first side of the interface block, each volatile memory stack including at least one of the one or more memory arrays; and a host chip bonded to a second side of the interface block opposite the first side, the host chip operable to communicatively couple with the interface block and control a function of the one or more volatile memory stacks.

Aspect 21: The semiconductor device of aspect 20, where the interface block includes: one or more conductive pads in the second side of the interface block that provide an evaluation interface for the interface block and the one or more volatile memory stacks.

Aspect 22: The semiconductor device of any of aspects 20 through 21, where the interface block includes: one or more conductive pads in the first side of the interface block, where the one or more volatile memory stacks are bonded to the interface block based at least in part on the one or more conductive pads.

Aspect 23: The semiconductor device of aspect 22, where the interface block includes: a plurality of vias extending through the first side of the interface block and coupled with the one or more conductive pads.

Aspect 24: The semiconductor device of any of aspects 20 through 23, where the one or more volatile memory stacks include: a plurality of vias in at least a first volatile memory of each volatile memory stack, where the first volatile memory is coupled with a second volatile memory of a volatile memory stack based at least in part on the plurality of vias.

Aspect 25: The semiconductor device of any of aspects 20 through 24, where the host chip includes: one or more conductive pads in a first side of the host chip, where the host chip is bonded to the second side of the interface block based at least in part on the one or more conductive pads.

Aspect 26: The semiconductor device of aspect 25, further including: a plurality of vias extending through the first side of the host chip and coupled with the one or more conductive pads.

Aspect 27: The semiconductor device of any of aspects 20 through 26, further including: a substrate positioned above the one or more volatile memory stacks, where a first side of the one or more volatile memory stacks is bonded to the substrate and a second side of the one or more volatile memory stacks opposite the first side of the one or more volatile memory stacks is bonded to the first side of the interface block.

Aspect 28: The semiconductor device of any of aspects 20 through 27, further including: a dielectric material positioned around the interface block, the one or more volatile memory stacks, and the host chip, where the dielectric material separates respective substrates associated with each volatile memory stack of the one or more volatile memory stacks.

Aspect 29: The semiconductor device of any of aspects 20 through 28, further including: one or more solder pads below the host chip, where a first side of the host chip is bonded with the second side of the interface block, and where the one or more solder pads are coupled with the host chip via a second side of the host chip opposite the first side of the host chip.

Aspect 30: The semiconductor device of any of aspects 20 through 29, where the interface block and the host chip have a same length along a width direction of the semiconductor device.

Aspect 31: The semiconductor device of any of aspects 20 through 29, where the interface block and the host chip have different respective lengths along a width direction of the semiconductor device, and where the interface block or the host chip includes a dielectric material along the width direction based on the different respective lengths.

Aspect 32: The semiconductor device of any of aspects 20 through 28, where the one or more volatile memory stacks of the semiconductor device includes at least eight volatile memory stacks.

Aspect 33: The semiconductor device of any of aspects 20 through 29, where: the one or more volatile memory stacks include one or more DRAM chips including the one or more memory arrays; and the host chip includes a graphics processing unit that is operable to control a function of the interface block, the one or more volatile memory stacks, or both.

An apparatus is described. The following provides an overview of aspects of the apparatus as described herein:

Aspect 34: A product formed by a process of: bonding a first side of an interface block to one or more volatile memory stacks; performing an evaluation procedure on the interface block and the one or more volatile memory stacks by probing one or more conductive pads of a second side of the interface block opposite the first side based at least in part on bonding the first side of the interface block; and bonding the second side of the interface block to a host chip based at least in part on performing the evaluation procedure, the host chip operable to communicatively couple with the interface block and control a function of the one or more volatile memory stacks.

An apparatus is described. The following provides an overview of aspects of the apparatus as described herein:

Aspect 35: A semiconductor device, including: an interface block including logic circuitry to operate one or more memory arrays; one or more volatile memory stacks bonded to a first side of the interface block, and each set of second semiconductor dies including at least one of the one or more memory arrays; and one or more first conductive pads formed in a second side of the interface block opposite the first side, the one or more first conductive pads providing an evaluation interface for the interface block and the one or more volatile memory stacks.

Aspect 36: The semiconductor device of aspect 35, where the interface block includes: one or more second conductive pads in the first side of the interface block, where the one or more volatile memory stacks are bonded to the interface block based at least in part on the one or more second conductive pads.

Aspect 37: The semiconductor device of any of aspects 35 through 36, where the interface block includes: one or more second conductive pads formed over the one or more first conductive pads, where the one or more second conductive pads provide an interface to couple with a host chip.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a semiconductor device, comprising:
bonding a first side of an interface block to one or more volatile memory stacks;
forming one or more conductive pads of a second side of the interface block opposite the first side based at least in part on bonding the first side of the interface block; and
bonding the second side of the interface block to a host chip based at least in part on forming the one or more conductive pads, the host chip operable to communicatively couple with the interface block and control a function of the one or more volatile memory stacks.

2. The method of claim 1, further comprising:
forming the interface block positioned on a carrier material, the interface block comprising one or more second conductive pads on the first side of the interface block, wherein:
bonding the first side of the interface block to the one or more volatile memory stacks is based at least in part on the one or more second conductive pads; and
the second side of the interface block is bonded to the carrier material prior to bonding the first side of the interface block.

3. The method of claim 2, further comprising:
forming a plurality of vias through the first side of the interface block, the plurality of vias coupled with the one or more second conductive pads.

4. The method of claim 2, further comprising:
forming a first wafer comprising a plurality of interface blocks including the interface block;
testing the plurality of interface blocks to determine whether each interface block is defective; and
dicing the first wafer to separate defective interface blocks from operable interface blocks.

5. The method of claim 4, further comprising:
selecting the interface block based at least in part on determining that the interface block is operable; and
forming a second wafer comprising the operable interface blocks including the interface block based at least in part on selecting the interface block, wherein bonding the interface block to the one or more volatile memory stacks is based at least in part on forming the second wafer.

6. The method of claim 1, further comprising:
forming the one or more volatile memory stacks on a carrier material; and
separating the one or more volatile memory stacks from the carrier material prior to bonding the first side of the interface block to the one or more volatile memory stacks.

7. The method of claim 6, further comprising:
forming a plurality of vias in at least a first volatile memory of each volatile memory stack, wherein the first volatile memory is coupled with a second volatile memory of a volatile memory stack based at least in part on the plurality of vias.

8. The method of claim 6, further comprising:
forming a dielectric material between each volatile memory stack of the one or more volatile memory stacks after bonding the first side of the interface block to the one or more volatile memory stacks; and
bonding a first side of the one or more volatile memory stacks to a silicon material, wherein a second side of the one or more volatile memory stacks opposite the first side of the one or more volatile memory stacks is bonded to the first side of the interface block.

9. The method of claim 1, further comprising:
performing an evaluation procedure on the interface block and the one or more volatile memory stacks by probing the one or more conductive pads in the second side of the interface block, wherein performing the evaluation procedure is based at least in part on forming the one or more conductive pads.

10. The method of claim 9, further comprising:
forming one or more second conductive pads over the one or more conductive pads on the second side of the interface block, wherein bonding the second side of the interface block to the host chip is based at least in part on forming the one or more second conductive pads.

11. The method of claim 1, further comprising:
forming the host chip positioned on a carrier material, the host chip comprising one or more second conductive pads in a first side of the host chip, wherein:
bonding the second side of the interface block to the host chip comprises bonding the second side of the interface block to the first side of the host chip based at least in part on the one or more second conductive pads; and
a second side of the host chip opposite the first side of the host chip is bonded to the carrier material prior to bonding the second side of the interface block to the host chip.

12. The method of claim 11, further comprising:
forming a plurality of vias through the first side of the host chip, the plurality of vias coupled with the one or more second conductive pads.

13. The method of claim 11, further comprising:
forming a first wafer comprising a plurality of host chips including the host chip;
testing the plurality of host chips to determine whether each host chip is defective; and
dicing the first wafer to separate defective host chips from operable host chips.

14. The method of claim 13, further comprising:
selecting the host chip based at least in part on determining that the host chip is operable; and
forming a second wafer comprising the operable host chips including the host chip based at least in part on selecting the host chip, wherein bonding the interface block to the host chip is based at least in part on forming the second wafer.

15. The method of claim 1, further comprising:
forming one or more solder pads coupled with the host chip, wherein a first side of the host chip is bonded with the second side of the interface block, and wherein the one or more solder pads are formed below a second side of the host chip opposite the first side of the host chip.

16. The method of claim 1, wherein:
the interface block comprises logic circuitry that is configurable to operate one or more memory arrays of the one or more volatile memory stacks;
the one or more volatile memory stacks comprise one or more dynamic random access memory (DRAM) chips comprising the one or more memory arrays; and
the host chip comprises a graphics processing unit that is operable to control a function of the interface block, the one or more volatile memory stacks, or both.

17. A semiconductor device, comprising:
an interface block comprising logic circuitry configured to operate one or more memory arrays;
one or more volatile memory stacks bonded to a first side of the interface block, each volatile memory stack comprising at least one of the one or more memory arrays; and
a host chip bonded to a second side of the interface block opposite the first side, the host chip operable to communicatively couple with the interface block and control a function of the one or more volatile memory stacks.

18. The semiconductor device of claim 17, wherein the interface block comprises:
one or more conductive pads in the second side of the interface block that provide an evaluation interface for the interface block and the one or more volatile memory stacks.

19. The semiconductor device of claim 17, wherein the interface block comprises:
one or more conductive pads in the first side of the interface block, wherein the one or more volatile memory stacks are bonded to the interface block based at least in part on the one or more conductive pads.

20. The semiconductor device of claim 19, wherein the interface block comprises:
a plurality of vias extending through the first side of the interface block and coupled with the one or more conductive pads.

21. The semiconductor device of claim 17, wherein the one or more volatile memory stacks comprise:
a plurality of vias in at least a first volatile memory of each volatile memory stack, wherein the first volatile memory is coupled with a second volatile memory of a volatile memory stack based at least in part on the plurality of vias.

22. The semiconductor device of claim 17, wherein the host chip comprises:
one or more conductive pads in a first side of the host chip, wherein the host chip is bonded to the second side of the interface block based at least in part on the one or more conductive pads.

23. The semiconductor device of claim 22, further comprising:
a plurality of vias extending through the first side of the host chip and coupled with the one or more conductive pads.

24. The semiconductor device of claim 17, further comprising:
a substrate positioned above the one or more volatile memory stacks, wherein a first side of the one or more volatile memory stacks is bonded to the substrate and a second side of the one or more volatile memory stacks opposite the first side of the one or more volatile memory stacks is bonded to the first side of the interface block.

25. The semiconductor device of claim 17, further comprising:
a dielectric material positioned around the interface block, the one or more volatile memory stacks, and the host chip, wherein the dielectric material separates respective substrates associated with each volatile memory stack of the one or more volatile memory stacks.

26. The semiconductor device of claim 17, further comprising:
one or more solder pads below the host chip, wherein a first side of the host chip is bonded with the second side of the interface block, and wherein the one or more solder pads are coupled with the host chip via a second side of the host chip opposite the first side of the host chip.

27. The semiconductor device of claim 17, wherein:
the one or more volatile memory stacks comprise one or more dynamic random access memory (DRAM) chips comprising the one or more memory arrays; and
the host chip comprises a graphics processing unit that is operable to control a function of the interface block, the one or more volatile memory stacks, or both.

28. The semiconductor device of claim 17, wherein the interface block and the host chip have a same length along a width direction of the semiconductor device.

29. The semiconductor device of claim 17, wherein the interface block and the host chip have different respective lengths along a width direction of the semiconductor device, and wherein the interface block or the host chip includes a dielectric material along the width direction based at least in part on the different respective lengths.

30. The semiconductor device of claim 17, wherein the one or more volatile memory stacks of the semiconductor device includes at least eight volatile memory stacks.

31. A product formed by a process of:
bonding a first side of an interface block to one or more volatile memory stacks;
forming one or more conductive pads of a second side of the interface block opposite the first side based at least in part on bonding the first side of the interface block; and
bonding the second side of the interface block to a host chip based at least in part on forming the one or more conductive pads, the host chip operable to communicatively couple with the interface block and control a function of the one or more volatile memory stacks.

32. A method for manufacturing a semiconductor device, comprising:
bonding a first side of an interface block to one or more volatile memory stacks;
forming one or more first conductive pads of a second side of interface block die opposite the first side based at least in part on bonding the first side; and
forming a dielectric material over the second side of the interface block based at least in part on forming the one or more first conductive pads, the dielectric material comprising one or more second conductive pads that are operable to couple the interface block with a host chip.

33. The method of claim 32, further comprising:
forming the interface block positioned on a carrier material, the interface block comprising one or more third conductive pads on the first side of the interface block, wherein:
bonding the first side of the interface block to the one or more volatile memory stacks is based at least in part on the one or more third conductive pads; and
the second side of the interface block is bonded to the carrier material prior to bonding the first side of the interface block.

34. The method of claim 32, further comprising:
forming the one or more volatile memory stacks on a carrier material; and
separating the one or more volatile memory stacks from the carrier material prior to bonding the first side of the interface block to the one or more volatile memory stacks.

35. A semiconductor device, comprising:
an interface block comprising logic circuitry to operate one or more memory arrays;
one or more volatile memory stacks bonded to a first side of the interface block, and each set of second semiconductor dies comprising at least one of the one or more memory arrays; and
one or more first conductive pads formed in a second side of the interface block opposite the first side, the one or more first conductive pads providing an evaluation interface for the interface block and the one or more volatile memory stacks.

36. The semiconductor device of claim 35, wherein the interface block comprises:
one or more second conductive pads in the first side of the interface block, wherein the one or more volatile memory stacks are bonded to the interface block based at least in part on the one or more second conductive pads.

37. The semiconductor device of claim 35, wherein the interface block comprises:
one or more second conductive pads formed over the one or more first conductive pads, wherein the one or more second conductive pads provide an interface to couple with a host chip.
